(19) United States
(12) Patent Application Publication
(10) Pub. No.: US 2022/0362976 A1
(43) Pub. Date: Nov. 17, 2022

(54) METHOD OF PRODUCING A COMPONENT SHIELDED FROM ELECTROMAGNETIC RADIATION

(71) Applicant: CARL FREUDENBERG KG, Weinheim (DE)

(72) Inventors: Volker Schroiff, Hemsbach (DE); Marco Sutter, Weinheim (DE); Matthias Hauer, Weinheim (DE); Eduard Grune, Edingen-Neckarhausen (DE)

(21) Appl. No.: 17/623,267

(22) PCT Filed: Jun. 29, 2020
(86) PCT No.: PCT/EP2020/068200

§ 371 Date: Dec. 28, 2021

(30) Foreign Application Priority Data
Jul. 4, 2019 (DE) 10 2019 118 092.9

(51) Int. Cl. B29C 45/16; C08F 297/04; C08K 13/04; C08L 53/02; C09D 153/02; C09D 5/24; C09D 7/40; C09D 7/61; H05K 9/00; B29C 45/00

(52) U.S. Cl. CPC B29C 45/164; C08F 297/04; C08K 13/04; C08L 53/02; C09D 153/02; C09D 5/24; C09D 7/70; C09D 7/61; H05K 9/0083; H05K 9/0047; B29C 45/0013; C08K 3/04

(57) ABSTRACT

A method produces a substrate shielded from electromagnetic radiation. The method includes i) providing a first polymer material (a) or a precursor thereof containing at least one conductive filler and at least a second polymer material (b) or precursor thereof; ii) obtaining a substrate by subjecting the first polymer material (a) or the precursor thereof and the second polymer material (b) or the precursor thereof to shaping with material bonding of the first polymer material (a) and the second polymer material (b), and polymerizing, if present, the precursors; and iii) at least partially surrounding an electronic component with the substrate obtained in step ii). A polymer component of the first polymer material (a) includes a thermoplastic elastomer or at least one thermoplastic elastomer, selected from the group consisting of, e.g., thermoplastic polyamide elastomers, thermoplastic copolyester elastomers, thermoplastic olefin-based elastomers, thermoplastic styrene block copolymers, polyether block amides, and mixtures thereof.

### CROSS REFERENCE TO RELATED APPLICATIONS

This application is a U.S. National Phase application under 35 U.S.C. § 371 of International Application No. PCT/EP2020/068200, filed on Jun. 29, 2020, and claims benefit to German Patent Application No. DE 10 2019 118 092.9, filed on Jul. 4, 2019. The International Application was published in German on Jan. 7, 2021 as WO 2021/001298 A1 under PCT Article 21(2).

### FIELD

The present invention relates to a method for producing a substrate shielded from electromagnetic radiation, the substrates and devices obtainable according to said method and their use for shielding electromagnetic radiation, especially in the field of electromobility.

### BACKGROUND

Electromagnetic waves have an electrical and a magnetic field component. The waves emitted by electronic components can lead to mutual electromagnetic interference (EMI). The enormous advances in semiconductor technology have made electronic components increasingly smaller and has significantly increased their density within electronic devices. The increasing complexity of electronic systems, e.g., in areas such as electromobility, aerospace technology, or medical technology, poses a great challenge to the electromagnetic compatibility of the individual components. In electric vehicles, for example, high-power electric drives are integrated in the smallest space and controlled by electronic components, wherein the individual components must not interfere with one another. In order to achieve electromagnetic compatibility, it is known to dampen electromagnetic interferences with the aid of shielding housings. The term “electromagnetic compatibility” (EMC) is defined, for example, in accordance with DIN VDE 0870 as the ability of an electrical device to function satisfactorily in its surroundings without unduly influencing this environment, which may also include other devices. The EMC must therefore fulfill two conditions, the shielding of the emitted radiation and the interference resistance to other electromagnetic radiation. In many countries, the corresponding devices must satisfy legal provisions. According to DIN VDE 0870, the electromagnetic interference (EMI) is the action of electromagnetic waves on circuits, devices, systems, or living beings. In the case of the affected objects, such an action can lead to acceptable but also unacceptable impairments, for example of the functionality of devices, or danger to persons. In such cases, appropriate protective measures must be taken. The frequency range relevant to EMI shielding is generally between 100 Hz and 100 GHz. The damping achieved by shielding an irradiated electromagnetic wave is generally composed of reflection and absorption in all shielding principles. During the absorption, the electromagnetic wave loses energy, which is converted into heat energy, wherein the absorption depends on the wall thickness of the shielding material. By contrast, the reflection is independent of the material thickness, depending on the frequency range, and can occur both on the front side and on the rear side and within the material.

In the medium frequency range, the electrical conductivity behavior of the materials can generally be used to assess the shielding directly. In the lower frequency range, the relative permeability can be used to assess the shielding, and in the upper frequency range, the reflection and also the vibration absorption can be used.

Electromagnetic compatibility of the components, as well as energy saving and thermal management, are the challenges for a successful electromobility technology. The use of modern brushless electric motors and diverse control units require the provision of electrical power in the form of alternating current and three-phase current. In this case, the electronic components emit unwanted magnetic, electrical, and electromagnetic vibrations of different frequencies, which on the one hand may be an interference source for other control units, or the control unit itself is disturbed in its function by the emitted vibrations of the other components. The electronic components are currently electromagnetically shielded by the use of aluminum housings so that they do not negatively influence each other in their functional effects. Aluminum as a shielding material, however, has high weight and high costs. There is thus a great need for substitution materials for aluminum and methods for producing electromagnetically shielded components based on these substitution materials.

It is known to use metallic housings made, for example, of aluminum to shield electromagnetic radiation. As a result of the high conductivities of the metals, good shielding effectiveness is achieved. However, the use of purely metallic shields is associated with various disadvantages, such as the complicated production by punching, bending, and applying corrosion protection, which is very cost-intensive. The freedom of design is also very limited in the case of metallic materials. Shields made of plastic can often be brought into the desired shape more easily than metals. Since most plastics are insulators, they can be made conductive by applying a surface coating, e.g., by electroplating or physical vapor deposition (PVD). However, the metallic coating of plastics generally requires a great deal of effort to prepare the components so coating adheres well.

It is furthermore known to produce electromagnetic shielding by using plastic composites (composite materials, compounds) that have a matrix of at least one polymer component and at least one filler with shielding properties. These plastic composites can be used in the form of coatings, insulating tapes, molded bodies, etc. Electrically conductive fillers, for example, can be dispersed in a matrix of at least one non-conductive polymer in order to produce conductive composites.

In Journal of Applied Polymer Science, vol. 112, 2073-2086 (2009), S. Geetha et al. give an overview of methods and materials for shielding electromagnetic radiation. Various plastic composites based on non-conductive polymers with a large variety of conductive fillers are mentioned. As an alternative, the use of conductive polymers and especially polyaniline and polypyrrole is discussed.

In the Indian Journal of Fiber & textile Research, vol. 39, 329-342 (2014), K. Jagatheesan et al. describe the electromagnetic shielding properties of composites based on conductive fillers and conductive fabrics. The focus here is on special fabrics, e.g., based on conductive hybrid yarns and a multiplicity of conductive threads, for shielding a widest possible frequency range.

WO 2013/021039 relates to a microwave-absorbing composition containing dispersed magnetic nanoparticles in a polymer matrix. The polymer matrix contains a highly branched nitrogen-containing polymer, wherein specifically a polyurethane based on a hyperbranched melamine with polyol functionality is used.

U.S. Pat. No. 5,696,196 describes a coating composition for shielding plastic against electromagnetic interference (EMI) and radio frequency interference (RFI). The described composition comprises an aqueous dispersion of a thermoplastic emulsion, an aqueous urethane dispersion, a glycol-based coalescing solvent, silvered copper flakes, conductive clay, and defoamers.

US 2007/0056769 A1 describes a polymeric composite material for shielding against electromagnetic radiation, said material comprising a non-conductive polymer, an inherently conductive polymer, and an electrically conductive filler. In order to produce the composite, the polymer components are brought into intensive contact. Suitable non-conductive polymers include elastomeric, thermoplastic, and thermosetting polymers, which may be selected from a variety of different polymer classes.

DE 10 2018 115 503, which has not yet been published, describes a composition for shielding against electromagnetic radiation, comprising a) at least one conductive filler and b) a polymer matrix containing at least one polyurethane containing urea groups. Unlike various embodiments of the present invention, DE 10 2018 115 503 does not describe how to produce an EMI-shielding substrate from this composition and at least one further polymer material by an injection-molding method.

DE 10 2014 015 870 describes a chassis component for motor vehicles made from a short-fiber-reinforced plastic, wherein the plastic may be, among other things, a carbon-reinforced plastic with a fiber length of between 0.1 and 1 mm. The chassis component is produced by manufacturing the core in a first injection-molding process and shaping the core in a second injection-molding process by overmolding with the same short-fiber-reinforced plastic.

JP H07-186190 describes a seven-layer injection-molded article, wherein four types of thermoplastic resins were used. The first and seventh layers, i.e., the surface layers consist of polyolefin resins. The second and sixth layers are a light-shielding layer consisting of polyolefin resins colored by carbon black or light-absorbing fillers. The second layer is an oxygen barrier resin. The third and fifth layers are a maleic anhydride graft-modified polyolefin resin.

JP 2005-229007 describes a resin housing having electromagnetic shielding properties. These are produced by injection molding using a thin film web having at least one conductive layer and an adhesive layer or by thermoforming. The conductive layer is either a layer of nickel, aluminum, silver, gold, steel, or brass obtained by metal vapor deposition or a metal foil of aluminum or copper.

WO 2014/175973 describes a method for producing EMI shielding for an electronic circuit board, wherein an electrically conductive thermoplastic film is used which contains a previously applied electrically conductive adhesive composition. The adhesive composition comprises a silicone adhesive, a compatible silane, and electrically conductive particles or fibers.

WO 2010/036563 describes an EMI shield with at least one compartment for enclosing the circuit of an electronic device. The shield includes an elastic layer made of a heat-deformable, electrically conductive foam, the layer having a first surface and a second surface defining a thickness dimension between them, and the layer having an inner portion surrounded by a circumferential section. The inner part of the layer is compressed through its thickness dimension to form an upper wall section of the shield, wherein the thickness dimension of the circumferential section extends downward from the upper wall section to form a side wall section of the shield which, together with the upper wall section, defines at least a part of the chamber.

WO 1997/041572 describes a heat-shrinkable sheath that shields against electromagnetic interference (EMI) and can be used to encase an elongated object with a given outer diameter. The sheath consists of a tubular outer element of indefinite length and an expanded inner diameter that is greater than the outer diameter of the object, an electrically conductive inner element, which is accommodated coaxially within the outer element and extends coextensively therewith, and a generally continuous, thermoplastic intermediate layer which is arranged between the outer and inner elements and extending coextensively therewith. The intermediate layer connects the inner element to the outer element substantially over its entire length in order to consolidate the casing into an integral structure. The outer element in turn is heat-shrinkable to a reclaimed, i.e., contracted, inner diameter that is smaller than the expanded inner diameter, in order to substantially adapt the casing to the outer diametrical extent of the object.

WO 2011/019888 describes a sealing arrangement equipped with a life detection device with respect to wear, thermal degradation, physical damage, chemical incompatibility, and structural disturbances within the sealing arrangement, and with a device for transmitting an output signal of the detection device in order to detect a change in the sealing environment or an imminent sealing failure.

Various established methods are known for producing plastic components from multiple materials, e.g., hard-soft composite components, and especially for producing surfaces on molded parts. These include special injection-molding methods, such as back injection molding and multi-component injection molding.

### SUMMARY

In an embodiment, the present disclosure provides a method of producing a substrate shielded from electromagnetic radiation. The method includes i) providing a first polymer material (a) or a precursor of the first polymer material (a) containing at least one conductive filler and at least a second polymer material (b) or a precursor of the second polymer material (b); ii) obtaining a substrate by subjecting the first polymer material (a) or the precursor of the first polymer material (a) and the second polymer material (b) or the precursor of the second polymer material (b) to shaping with material bonding of the first polymer material (a) and the second polymer material (b), and polymerizing, if present, the precursors; and iii) at least partially surrounding an electronic component with the substrate obtained in step ii). A polymer component of the first polymer material (a) includes a thermoplastic elastomer or at least one thermoplastic elastomer, selected from the group consisting of thermoplastic polyamide elastomers, thermoplastic copolyester elastomers, thermoplastic olefin-based elastomers, thermoplastic styrene block copolymers, thermoplastic polyurethane-based elastomers, thermoplastic vulcanizates, crosslinked thermoplastic olefin-based elastomers, polyether block amides, and mixtures thereof.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1: Sample body with injected seal and overmolded with an EMI-shielding composition according to an embodiment of the invention; and

FIG. 2: Test samples with injected perforated EMI-shielding composition according to an embodiment of the invention. In addition to good EMI shielding properties, perforation also provides good NVH properties.

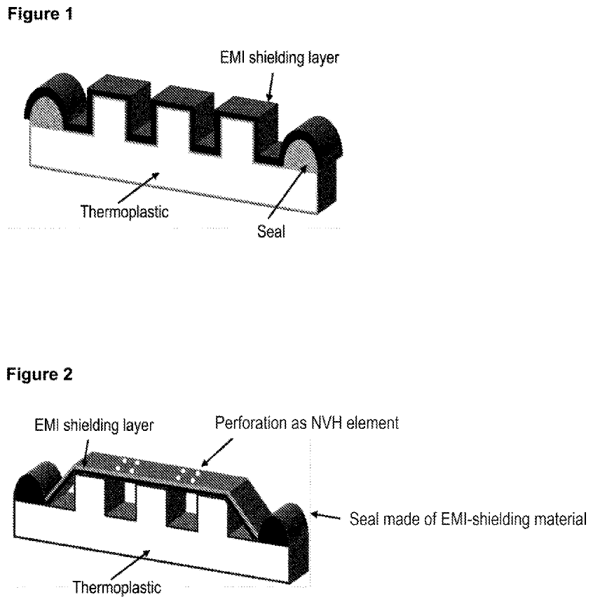

### DETAILED DESCRIPTION

Embodiments of the present invention provide a method for producing substrates (components) that are shielded from electromagnetic radiation, said method overcoming many disadvantages, including those described above.

The methods described in the state of the art for producing electromagnetically shielding surfaces on plastic components generally provide for the application of the coating as an additional work step following the shaping. Such methods have the following disadvantages:

Additional work steps result in higher production costs. This leads to an economic disadvantage, e.g., in comparison to shielding devices made of die-cast aluminum.

Spraying methods lead to a frequently considerable loss of material due to the so-called over-spray.

The layer thicknesses of the coatings obtained by spray application are generally not uniform with respect to the component surface. It is also difficult to apply the conductive layers to the desired small thickness, e.g., of at most 1 mm.

The integration of further functions into the component, such as touch-sensitive sensors, switches, etc., or additional heat or light protection, is limited by the method.

There is therefore a need for a method for producing plastic components having a layer capable of shielding against electromagnetic radiation, wherein the EMI shielding and possibly further functions are integrated into the surface of the component directly during the production of the molded part.

Surprisingly, it has been found by various embodiments of the present invention that this need can be solved by a method in which, in order to produce a substrate shielded from electromagnetic radiation, a first polymer material containing at least one filler for shielding electromagnetic radiation can be bonded to at least a second polymer material by a special injection-molding method and simultaneously subjected to shaping.

The method according to embodiments of the invention and the substrates and components obtained accordingly have the following advantages:

The method according to various embodiments of the invention makes it possible to produce an EMI-shielded substrate without first shaping the component separately and only subsequently coating it.

EMI coatings with a small thickness and/or a small deviation (variance) from the desired layer thickness can be produced.

In addition to EMI shielding, it is possible to integrate additional functions into the component directly during the shaping of the component. This enables, for example, the integrated production of multi-part EMI-shielded housings with a conductive seal for contacting the individual housing parts or the integration of a heat shield.

Elastomeric polymer materials that can absorb energy of different shapes (especially different wavelength ranges) can be used to shield the electromagnetic radiation. Thus, undesired mechanical vibrations can also be avoided. This has an advantageous effect, for example, on the NVH behavior (NVH=Noise, Vibration, Harshness) of the components. Furthermore, additional functionalities may be provided during the production of the EMI-shielded substrate. By using a polymer film that at least partially encloses the substrate, improved crash safety can, for example, be achieved, or by using heat-resistant polymers, improved heat resistance can be achieved.

A combination of polymer materials can be used to produce the substrates, wherein a component gives the substrate the structural strength, which is not negatively affected by the further component used for EMI shielding.

Material losses, as are common when applying coatings by spraying methods, are avoided.

A first subject matter of the invention is a method for producing a substrate shielded from electromagnetic radiation, wherein:
i) a first polymer material (a) or a precursor thereof containing at least one conductive filler and at least a second polymer material (b) or a precursor thereof are provided,
ii) the polymer materials (a) and (b) or their precursor(s) provided in step i) are subjected to shaping with material bonding of the polymer materials (a) and (b), and in the process, the precursors, if any, are polymerized.

Within the scope of the invention, a substrate shielded from electromagnetic radiation also refers to a substrate capable of shielding electromagnetic radiation, i.e., a substrate shielding electromagnetic radiation.

In one variant, an electronic component is coated and/or encased by a substrate according to an embodiment of the invention in order to shield the electromagnetic waves emitted by the electronic component so as not to influence the environment in an undue manner. In a further variant, an electronic component is coated and/or encased by a substrate according to a further embodiment of the invention in order to prevent electromagnetic waves from the environment from influencing the coated and/or encased electronic component in an impermissible manner. The substrate according to an embodiment of the invention can be an integral component of the electronic component.

In a further step of the method according to preferred embodiments of the invention, an electronic component is coated and/or encased by the substrate obtained in step ii) and/or an electronic component is embedded in the substrate obtained in step ii).

Specifically, at least one of the components provided in step i), selected from the polymer material (a), the precursor for the polymer material (a), the polymer material (b), and the precursor for the polymer material (b), is used in flowable form for shaping in step ii) or is shapable under the method conditions in step ii).

A first preferred embodiment of the method according to the invention is the back injection molding of films and composite materials. Another preferred embodiment of the method according to the invention is multi-component injection molding (also referred to as composite injection molding or overmolding).

A further subject matter of the invention is a substrate that is obtainable by the method described above and below.

A further subject matter of the invention is a device for shielding against electromagnetic radiation, said device comprising such a substrate or consisting of such a substrate.

A further subject matter of the invention is the use of a substrate according to the invention for shielding against electromagnetic radiation.

Polymer materials (a), (b), and (c) in the sense of various embodiments of the invention are materials that contain at least one polymer or consist of at least one polymer. In addition to at least one polymer, the polymer materials (a), (b), and (c) may contain at least one further component, e.g., fillers, reinforcing materials, or additives different therefrom. In a particular embodiment, the polymer materials (a), (b), and (c) are present as composite (composite material).

The polymer materials (a), (b), and, if present, (c) are used as separate components in the method according to an embodiment of the invention and are bonded together to produce the substrates according to embodiments of the invention. It is an essential feature of the method according to various exemplary embodiments of the invention that the bonding of the polymer material (a), which contains at least one conductive filler (or the precursor thereof) to the polymer material (b) (or the precursor thereof) and the shaping of the composite of (a) and (b) are carried out in one step.

Various variants for bonding and shaping (a) and (b) in one step are described in more detail below. One example is multi-component injection molding for producing substrates in the form of injection-molded parts, which can consist of two or more than two plastic materials. It is a feature of the multi-component injection-molding methods that can be used according to embodiments of the invention that they can have two or more than two injection units, but only one closing unit is required. According to exemplary embodiments of the invention, substrates having only one tool can thus be produced in one work process.

In order to produce the substrate shielded from electromagnetic radiation, the polymer materials (a) and (b) or the shaped composite of (a) and (b) can be bonded to at least one further polymer material (c) or a precursor thereof. Bonding with the at least one further polymer material (c) or precursor thereof may be carried out in method step ii). Alternatively, the formed composite of (a) and (b) may be bonded at least to one further polymer material (c) or a precursor thereof in at least one separate step iii). Optionally, the composite of (a), (b), and (c) can be subjected to at least one further shaping. This shaping can be carried out simultaneously with the bonding in step ii) or step iii) or in a separate step. Alternatively, a shaped composite of (a), (b), and (c) from step ii) may also be bonded to a further polymer material (c) or a precursor thereof in at least one separate step iii).

In principle, the polymer materials (a), (b), and (c) may all contain the same polymers or partly different polymers or completely different polymers.

The term “thermoplastics” within the meaning of the invention refers to polymers that can be reversibly deformed above a certain temperature, wherein this process can, theoretically, be repeated as many times as desired.

Thermoplastics are made up of sparsely branched or non-branched polymer chains that are bonded together (i.e., uncrosslinked) only by weak physical bonds and not by chemical bonds. This distinguishes thermoplastics from thermosets and (classic, i.e., non-thermoplastic) elastomers that can no longer be thermoplastically deformed after their production.

The term “elastomers” within the meaning of the invention refers to dimensionally stable but elastically deformable plastics having a glass transition temperature below the temperature at which the polymers are normally used. Elastomers can deform elastically under tensile and compressive stress but then return to their original, undeformed shape.

A specific form of the elastomers are thermoplastic elastomers having thermoplastic properties within certain temperature ranges. Thermoplastic elastomers usually behave like classic elastomers at low temperatures. When heat is applied, on the other hand, they are plastically deformable and exhibit thermoplastic behavior.

For shaping in step ii), at least one of the components provided in step i) is used in flowable form or can be shaped under the method conditions in step ii). As the person skilled in the art knows, the thermal behavior of the various types of polymers (amorphous thermoplastics, thermoplastic elastomers, partially crystalline thermoplastics, elastomers, thermosets) is characterized by state ranges, wherein the thermal-mechanical properties do not change or change only slightly within a state range. Below the glass transition temperature TG, polymers generally exist in a solid, glassy state.

Amorphous thermoplastics enter a thermoelastic state above TG and can be changed in shape. This change in shape is initially reversible; the polymer material is only shapable at a higher temperature by so-called “thermoforming.” Amorphous thermoplastics do not have a precisely defined melting point. Beyond the flow temperature, the material becomes soft and flowable (plasticized) and can then also be processed by primary shaping (such as injection molding).

Thermoplastic elastomers are plastics that behave like classic elastomers above TG, i.e., they are (visco-)plastic and not shapable. When heated above the melting temperature, they exhibit thermoplastic behavior, the material becomes flowable and can be processed by primary shaping (such as injection molding).

Elastomers, in the form of their not-yet-crosslinked precursors, can be converted into a flowable form and used for shaping in step ii). The influence of heat causes elastomers to vulcanize so that, unlike thermoplastics, they cannot be remelted and reshaped.

Thermosets also generally cure by the action of heat. After curing, remelting and reshaping is no longer possible. Thermosets, in the form of their not-yet-cured precursors, can be converted into a flowable form and used for shaping in step ii). In a suitable embodiment, the precursor is injected into a mold at a comparatively low temperature and cured there by a higher temperature. The thermal behavior of the polymer materials used according to embodiments of the invention, i.e., under which conditions they are shapable or flowable, are part of the expert knowledge or can be determined by the person skilled in the art by routine experiments.

A material bond is formed by atomic or molecular forces between the connection partners. The material bonds of plastics include the adhesive connections and welded connections; injection molding methods also lead to material bonds. A material bond is a generally non-detachable connection.

Form fits result from the engagement of at least two connection partners with one another. As a result, the connection partners cannot detach even without or in the event of interrupted force transmission.

Methods according to various embodiments of the invention can be used to produce substrates which are advantageously suitable for shielding electromagnetic radiation in the entire frequency range in which such measures are required, in order to reduce or avoid undesirable interference by electromagnetic radiation. The frequency range relevant to EMI shielding is generally in a range of about 2 Hz to 100 GHz, preferably of 100 Hz to 100 GHz. The wavelength range that is particularly interesting for shielding in automotive applications is in a range of 100 kHz to 100 MHz. In particular, the wavelength range for shielding in automotive applications is in a medium frequency range of 3 Hz to 10 kHz and a radar range of 23 GHz to 85 GHz. The compositions according to exemplary embodiments of the invention are well suited for this purpose. The substrates produced by the exemplary methods according to embodiments of the invention are also particularly suitable for shielding low and medium frequencies. For example, a material for deflecting magnetic fields, such as a magnetic material, can be used as a filler. Furthermore, a material for reflecting electromagnetic waves having a high frequency, e.g., a carbon-rich conductive nanomaterial, can also be used as a filler. Suitable combinations of fillers can be used for broadband application.

In a special first embodiment, a back-injection-molding method for producing a substrate shielded from electromagnetic radiation is provided.

Multi-component injection molding is used to produce injection-molded parts that consist of two or more different plastics. In the simplest case, the plastics differ only by color in order to achieve a certain design. However, different materials and thus different properties can also be combined in a targeted manner.

As in the case of back injection molding, there are also various execution techniques, for example composite injection molding or sandwich injection molding. Composite injection molding requires an injection-molding machine with two or even more injection units but only one closing unit. The parts can thus be produced cost-effectively with only one tool in one work process. The injection units should work in harmony but should also always be controllable independently of one another. The components can be injected by a single special nozzle or introduced into the tool at different locations.

Back injection molding produces (embossed/functionalized) molded parts consisting of a polymeric carrier (substrate) and a cover material (decorative material). There are various execution techniques, such as in-mold decoration (IMD), film insert molding (FIM), in-mold labeling (IML), in-mold coating (IMC), or in-mold painting (IMP). They all have in common that a pre-treated (embossed/functionalized) film is inserted into an injection molding tool and back-injection-molded and embossed with a further plastic, resulting in a plastic part with functionality or film coating.

In particular, at least one of the following techniques is used for back injection molding: in-mold decoration (IMD), film-insert molding (FIM), roll-to-roll, in-mold labeling (IML), in-mold coating (IMC), or in-mold painting (IMP).

The in-mold decoration method is a combination of hot stamping and film back injection molding. It is used to emboss a functionality from a carrier film, a special IMD film, onto a substrate. The functionalized and/or embossed carrier film is placed into the injection molding tool. In the second step, the plastic material is injected. In the final step, the obtained molded body is removed from the tool and the carrier film is separated. A plastic molded body with an embossed functionality is obtained.

In particular, according to embodiments of the invention, the carrier film in the IMD method comprises a first polymer material (a), which contains at least one filler for shielding electromagnetic radiation. In particular, according to exemplary embodiments of the invention, the plastic material comprises at least a second polymer material (b).

In the film insert molding method (FIM), the functionalized carrier film becomes part of the finished substrate. First, the carrier material, the embossing foil, is functionalized (coated), preformed, and punched out. The film cut into shape is placed into the injection molding tool and back-injection-molded with a plastic material. The exact order of the method steps is flexible. At the end, the carrier film is removed.

In particular, according to embodiments of the invention, the carrier film in the FIM method comprises the first polymer material (a), which contains at least one filler for shielding electromagnetic radiation. In particular, according to exemplary embodiments of the invention, the plastic material comprises at least a second polymer material (b).

A roll-to-roll (R2R) method can also be used for processing carrier films.

The in-mold labeling method is very similar to classic film back injection molding, except that label films are used here. These films are thinner. This film can be introduced into the injection molding tool either as rolled material or as a finished cut. At the end, the label film is removed.

In particular, according to embodiments of the invention, the carrier film in the IML method comprises the first polymer material (a), which contains at least one filler for shielding electromagnetic radiation. In particular, according to exemplary embodiments of the invention, the plastic material comprises at least a second polymer material (b).

In-mold coating is a combination of spraying and injection molding. First, a coating is applied into the injection molding tool using a spray gun. After the material has dried, the plastic material is back-injection-molded.

In particular, according to embodiments of the invention, the coating in the IMC method comprises the first polymer material (a), which contains at least one filler for shielding electromagnetic radiation. In particular, according to exemplary embodiments of the invention, the plastic material comprises at least a second polymer material (b).

In the in-mold painting method, the plastic material is sprayed in the first step, and the coating is sprayed on in the second step, i.e., the process steps are carried out in reverse order to the process steps of the IMC method.

In particular, the coating in the IMP method comprises the first polymer material (a), which contains at least one filler for shielding electromagnetic radiation. In particular, the plastic material comprises at least a second polymer material (b).

### Composites

In particular, in step i) of an embodiment of the method according to the invention, one of the polymer materials (a) or (b) is provided in the form of a composite. In a preferred embodiment, one of the polymer materials (a) or (b) is provided in the form of a layered composite. This is particularly advantageous if an embodiment of the method according to the invention is used for back injection molding. In a particular embodiment, component b) is provided in the form of a composite.

A composite or even composite material is a material made of two or more bonded materials that has different material properties than its individual components. Bonding is achieved by a material bond, a form fit, or a combination of both. Its constituents (phases) may originate from one and the same or from different main groups of materials. The main groups of materials include metals, ceramics, glasses, polymers, and composite materials. In the context of the invention, the term “composite” includes both composite materials and material composites. Composite materials are at least two-phase (i.e., heterogeneous) but appear macroscopically homogeneous. When viewed with the naked eye, they often appear to be a single material. Material composites are generally recognizable to the naked eye as composites of several different materials. A layered composite (laminate) is a preferred embodiment of a material composite. Laminates consist of at least two layers lying on top of one another. The special case of three layers where the two outer layers are identical is also referred to as a sandwich composite.

The composite preferably comprises at least one of the polymer materials (a) or (b) and at least one further component (K) different therefrom. Specifically, the composite comprises a polymer material (b) and at least one further component (K) different therefrom. The component (K) itself may be a composite material. The further component (K) is preferably selected from among polymers, polymeric materials, metals, metallic materials, ceramic materials, mineral materials, textile materials, and combinations thereof.

In a particularly preferred embodiment, the further component (K) is selected from polymer films, polymer molded bodies, metal foils, metal molded bodies, reinforced and/or filled polymer materials, and combinations thereof.

Suitable polymers are selected from elastomers, thermoplastics, thermosetting plastics. With regard to suitable and preferred plastics, reference is made to the statements relating to the polymer material (b) to the full extent.

Suitable metals are selected from aluminum, titanium, magnesium, copper, etc., and alloys thereof.

Ceramic materials are generally inorganic, non-metallic, and polycrystalline. The term “non-metallic” is understood to mean that ceramic materials substantially do not contain any elementary metals. The production of a ceramic material may involve, for example, subjecting the ceramic-forming inorganic particulate raw materials, a liquid, and optionally at least one organic binder to thermal treatment (sintering). In principle, materials made of oxide ceramics and non-oxide ceramics are suitable for use in the method according to exemplary embodiments of the invention. Suitable oxide ceramics are selected from single-component systems and multi-component systems. Preferred oxide ceramics are selected from aluminum oxide, magnesium oxide, zirconium oxide, titanium dioxide, aluminum titanates, mullite (mixture of aluminum and silicon oxide), lead zirconate titanates, and mixtures of zirconium oxide and aluminum oxide. Suitable non-oxide ceramics are selected from carbides, for example silicon carbide or boron carbide, nitrides, for example silicon nitride, aluminum nitride, or boron nitride, borides, and silicides.

Suitable metallic materials comprise at least one metal and at least one material different therefrom. The materials different from metal are preferably selected from ceramic materials, organic materials, and mixtures thereof. A preferred embodiment of the metallic materials are metal matrix composites (MMC) comprising a continuous metal matrix and a discontinuous ceramic and/or organic reinforcement. The reinforcement is preferably in the form of fibers or whiskers. The metal is selected, for example, from aluminum, titanium, magnesium, and copper. The matrix may be present as elemental metal or in the form of an alloy. Ceramic particles (e.g., silicon carbide), short fibers, continuous fibers (e.g., carbon-based), or foams are suitable as the reinforcing phase. A further preferred embodiment of the metallic materials are the materials obtainable by the metal powder injection molding (MIM) method.

In particular, the composite comprises at least one reinforced and/or filled plastic material. The reinforcing material is preferably selected from fibrous reinforcing materials, woven fibrous reinforcing materials, scrim fibrous reinforcing materials, knitted fibrous reinforcing materials, and knitted fibrous reinforcing materials, and mixtures thereof. The filler is preferably selected from particulate fillers, such as kaolin, chalk, wollastonite, talc, calcium carbonate, silicates, aluminum oxide, titanium dioxide, zinc oxide, glass particles, and mixtures thereof. Preferred reinforced plastic materials are fiber-plastic composite materials, such as carbon-fiber-reinforced plastic (CFRP), glass-fiber-reinforced plastic (GFRP), aramid-fiber-reinforced plastic (AFRP), natural fiber-reinforced plastic (NFRP), etc.

In a first particularly preferred embodiment, in step i) a composite is provided as the polymer material (a), which composite comprises the polymer component of the polymer material (a) as a coating on a polymer film, and this composite is materially bonded to the polymer material (b) in step ii) by injection molding. In a second particularly preferred embodiment, a composite is provided as a polymer material (b) in step i), which composite comprises the polymer component of the polymer material (b) as coating on a polymer film and this composite is materially bonded to the polymer material (a) in step ii) by injection molding.

In particular, step i) provides a composite comprising the polymer component of the polymer material (a) as a coating on a polymer film. This composite is materially bonded in step ii) to the at least one polymer material (b) by injection molding.

The polymer film serves as carrier material or transfer material for the polymer component of the polymer material (a) or of the polymer material (b) located thereon. Consequently, in order to provide a corresponding polymer material (a) or (b), the polymer film should be coated with the polymer component of the polymer material (a) or (b).

In principle, the polymer film should be suitable for coating with one of the polymer components (a) or (b). In the IMD, IFM, and IML methods, the polymer film should also be capable of being detachable from the substrate after the injection-molding process, i.e., after completion of step ii). In this variant, the polymer film is exclusively transfer material. In the IMC and IMP methods, the polymer film is part of the substrate. It then functions, for example, as a carrier material, a material for improving mechanical strength, decoration, etc.

Suitable polymer films that enable simple detachment include, for example, silicones, polyethylene terephthalates, polymer-coated paper, such as silicone paper, etc. Suitable polymer films that remain in the substrate include, for example, polypropylene, plasma-treated films, films having fluorinated surfaces, etc.

In a particular first variant, the polymer film is detached from the obtained injection-molded part after completion of injection-molding step ii).

In a special second variant, after completion of injection-molding step ii), the polymer film remains bonded to the obtained injection-molded part of the obtained substrate.

In a special second embodiment, a composite injection method for producing a substrate shielded from electromagnetic radiation is provided.

In composite injection molding, a first plastic component is injected into a mold (cavity). Once the cavity is filled, the second plastic component is injected or overmolded. This method makes it possible to combine complex components with different material properties. The various execution techniques are known to the person skilled in the art, such as core-back methods, conversion or transfer technique, rotary plate technique, or sliding technology.

In a particular embodiment, the polymer materials (a) and (b) provided in step i) can both be plasticized and are materially bonded in step ii) by multi-component injection molding.

In particular, at least one of the following techniques is used for multi-component injection molding: core-back technique, transfer technique, turning technique, index plate technique, shifting technique, sandwich technique.

In the transfer technique, a pre-molded part is transferred after the first injection process into a new tool cavity with space for the pre-molded part and the new component.

In the index plate technique (transfer technique), a pre-molded part is transferred after the first injection process into a new tool cavity with space for the pre-molded part and the new component, which can be applied on both sides of the pre-molded part.

In the turning/shifting technique, the tool (usually only one half) is turned or shifted to a new position after the first injection process and the pre-molded part is overmolded in the new position with another nozzle.

In the core-back technique, a core is retracted in the tool to make room for the component to be added. This technique is used in particular in the production of equipment housings with different color regions.

In the sandwich method, parts are usually created in which the internal component is not visible because it is completely surrounded by the outer material. Sandwich injection molding uses the laminar flow of the masses as they flow into the tool cavity (mold cavity). The melts fill the cavity one by one from the gate. The first inflowing molding compound is continuously placed against the wall, where it is finally pushed by the second component flowing inside. Two injection units work together on one injection head, which, depending on the control by valves or multiple shut-off nozzles, allows the masses to enter from all injection units as desired. The laminar flow ensures that this complete coating of the components around each other succeeds perfectly down to the smallest wall thicknesses. The gate can be sealed by the first component.

In one particular embodiment of the method according to the invention, an additional function is integrated into the substrate by one or more of the following measures:

forming a substrate with a sensor function,

using at least one component for preventing mechanical vibrations,

using at least one component for improving crash protection,

using at least one component to increase dielectric strength,

using at least one component with corrosion-protection function,

using at least one component with oxidation-protection function,

using at least one component with light-protection function,

using at least one component as a heating element,

using at least one component which has thermoelectric properties and as a result can generate electric currents,

injection-molding sealing elements,

injection-molding mounting and/or connecting elements.
Further possible measures for integrating an additional function into the substrate include, for example:

injection molding of decorative surface components,

using at least one decorative polymer film,

injection molding of stiffening elements (ribs, rib structures), etc.

The avoidance of mechanical vibrations is particularly important in the automotive sector to prevent impairment of driving comfort. The audible or perceptible vibrations in motor vehicles or on engines are collectively referred to as “Noise, Vibration, Harshness” (NVH). In order to avoid them, components are used that prevent the local introduction of force from a vibration source into vibration-transmitting media.

### Polymer Materials

The polymer materials a), b), and c) contain at least one polymer or consist of at least one polymer which is preferably selected from amorphous thermoplastics, thermoplastic elastomers, partially crystalline thermoplastics, elastomers, thermosetting plastics, and mixtures thereof.

The polymer materials a), b), and c) contain at least one polymer or consist of at least one polymer, which is particularly preferably selected from polyurethanes, silicones, fluorosilicones, polycarbonates, ethylene vinyl acetates (EVA), acrylonitrile-butadiene-acrylates (ABA), acrylonitrile-butadiene rubbers (ABN), acrylonitrile-butadiene-styrenes (ABS), acrylonitrile-methyl-methacrylates (AMMA), acrylonitrile-styrene-acrylates (ASA), cellulose acetates (CA), cellulose acetate butyrates (CAB), polysulfones (PSU), poly(meth)acrylates, polyvinyl chlorides (PVC), polyphenylene ethers (PPE=polyphenylene oxides (PPO)), polystyrenes (PS), polyamides (PA), polyolefins, e.g., polyethylene (PE) or polypropylene (PP), polyketones (PK), e.g., aliphatic polyketones or aromatic polyketones, polyetherketones (PEK), e.g., aliphatic polyetherketones or aromatic polyetherketones, polyimides (PI), polyetherimides, polyethylene terephthalates (PET), polybutylene terephthalates (PBT), fluoropolymers, polyesters, polyacetals, e.g., polyoxymethylene (POM), liquid crystal polymers, polyethersulfones (PES), epoxy resins (EP), phenolic resins, chlorosulfonates, polybutadienes, polybutylene, polyneoprenes, polynitriles, polyisoprenes, natural rubbers, copolymer rubbers, such as styrene-isoprene-styrenes (SIS), styrene-butadiene-styrenes (SBS), ethylene-propylenes (EPR), ethylene-propylene-diene rubbers (EPDM), styrene-butadiene rubbers (SBR), and their copolymers, and mixtures (blends) thereof.

Preferred aliphatic and aromatic polyetherketones are aliphatic polyetheretherketones or aromatic polyetheretherketones (PEEK). A particular embodiment is aromatic polyetheretherketones.

Within the meaning of the invention, the term “polyurethanes” also includes polyureas and polyurethanes containing urea groups.

Suitable thermosets include urea-formaldehyde resins, melamine resins, melamine formaldehyde resins, melamine urea-formaldehyde resins, melamine urea-phenol-formaldehyde resins, phenol-formaldehyde resins, resorcinol-formaldehyde resins, crosslinkable isocyanate-polyol resins, epoxy resins, acrylates, methacrylates, polystyrenes, and polyester resins.

Suitable thermoplastic elastomers include thermoplastic polyamide elastomers (TPA), thermoplastic copolyester elastomers (TPC), thermoplastic olefin-based elastomers (TPO) (specifically PP/EPDM), thermoplastic styrene block copolymers (TPS) (specifically styrene-butadiene-styrene (SBS), SEBS, SEPS, SEEPS, and MBS), thermoplastic polyurethane-based elastomers (TPU), thermoplastic vulcanizates (TPV), and olefin-based crosslinked thermoplastic elastomers (especially crosslinked PP/EPDM and crosslinked ethylene-propylene copolymers (EPM)), and polyether block amides (PEBA).

Thermoplastic styrene block copolymers (TPS) are selected, in particular, from SEBS, SEPS, SBS, SEEPS, SiBS, SIS, SIBS, or mixtures thereof, in particular SBS, SEBS, SEPS, SEEPS, MBS, and mixtures thereof.

Thermoplastic olefin-based elastomers (TPO) are selected in particular from PP/EPDM and ethylene-propylene copolymers (EPM).

Thermoplastic polyurethane-based elastomers (TPU) are in particular derived from at least one polymeric polyol, specifically selected from at least one polyester diol, polyether diol, polycarbonate diol, and mixtures thereof. A particular embodiment is a TPU incorporating at least one mixture of polymeric polyols comprising at least one polyester diol, at least one polyether diol, and at least one polycarbonate diol.

Thermoplastic vulcanizates (TPV) are derived in particular from a styrene block copolymer having a reactive or crosslinkable hard block comprising aromatic vinyl repeating units and a crosslinkable soft block comprising olefin or diene repeating units.

Suitable elastomers include acrylonitrile-butadiene-acrylates (ABA), acrylonitrile-butadiene rubbers (ABN), acrylonitrile-chlorinated polyethylene-styrene (A/PE-C/S), acrylonitrile/methylmethacrylate (A/MMA), butadiene rubber (BR), butyl rubber (IIR), chloroprene rubber (CR), ethylene-ethylacrylate copolymers (E/EA), ethylene-propylene-diene rubber (EPDM), ethylene-vinyl acetate (EVA), fluorine rubber (FPM or FKM), isoprene rubber (IR), natural rubber (NR), polyisobutylene (PIB), elastomeric polyurethanes, polyvinyl butyral (PVB), silicone rubbers, styrene-butadiene rubber (SBR), vinyl chloride/ethylene (VC/E), and vinyl chloride-ethylene-methacrylate (VC/E/MA).

In a particular embodiment, the polymer materials a), b), and c) comprise at least one polymer or consist of at least one polymer selected in particular from thermoplastic olefin-based elastomers (TPO) (especially PP/EPDM), thermoplastic styrene block copolymers (TPS), especially styrene-butadiene-styrene (SBS), SEBS, SEPS, SEEPS, and MBS, thermoplastic polyurethane-base elastomers (TPU), and thermoplastic vulcanizates (TPV).

### Polymer Material (a)

High degrees of filling and very good shielding effectiveness (SE) can be achieved with the polymer materials (a) used according to exemplary embodiments of the invention, which contain at least one conductive filler. The shielding effectiveness is composed of proportions of absorption SEA, reflection SER, and multi-reflection SEM. Specifically, polyurethanes and specific polyurethanes containing urea groups have a high degree of compatibility with a large number of different fillers suitable for EMI shielding. Due to the high flexibility of the substrates according to various embodiments of the invention with regard to the type and amount of conductive fillers contained and the possibility of using further polymer components, especially also conductive polymers, the respective desired proportion of absorption and reflection in the shielding effectiveness can be well controlled. Thus, the shielded substrates according to exemplary embodiments of the invention fulfill the requirements for electromagnetic compatibility of the material, as defined, for example, in the corresponding CISPR standards (Comité international spécial des perturbations radioélectriques=International Special Committee on Radio Interference). At the same time, the substrates according to various embodiments of the invention are characterized by an overall good application profile. This includes the fact that they can withstand mechanical, thermal, or chemical stresses and are characterized, for example, by good scratch resistance, adhesion, corrosion resistance, or elasticity.

The polymer material (a) preferably contains 15 to 99.5 wt. %, particularly preferably 20 to 99 wt. %, of at least one polymer component based on the sum of the polymer component and at least one conductive filler. The term “polymer component” also comprises polymerized precursors of the polymer material (a).

The polymer material a) preferably comprises or consists of at least one polymer selected from thermoplastics, thermoplastic elastomers, elastomers, and mixtures thereof. Thermoplastics, thermoplastic elastomers, and mixtures thereof are preferred.

The polymer component of the polymer material (a) is preferably selected from polyolefin homopolymers or copolymers, liquid silicone rubbers, epoxy polymers, polyurethanes, and mixtures thereof.

In a preferred embodiment, the polymer component of the polymer material (a) contains or consists of at least one polyolefin homopolymer or copolymer. The polyolefins preferably contain one or more C1-C4 olefins polymerized therein, preferably selected from ethylene, propylene, 1-butene, or isobutene. Suitable polyolefin homopolymers or copolymers are selected from polyethylene (PE), polypropylene (PP), polymethylpentene (PMP), polyisobutene (PIB), polybutene (PB), ethylene/propylene copolymers, ethylene-propylene-diene copolymers (EPDM), and mixtures thereof.

In a further preferred embodiment, the polymer component of the polymer material (a) contains or consists of a liquid silicone rubber (LSR). EP0875536A2 describes a self-adhering addition-crosslinked silicone rubber mixture containing a) an SiH crosslinker containing at least 20 SiH groups and b) an epoxy-functional alkoxysilane and/or alkoxysiloxane. EP1854847A1 describes a curable two-component system containing at least one diorganopolysiloxane and at least one crosslinker containing SiH. Suitable liquid silicone rubbers are commercially available, e.g., the two-component silicone elastomers of the Elastosil brands of Wacker Chemie AG, Munich, Germany.

In a further preferred embodiment, the polymer component of the polymer material (a) contains or consists of a polyurethane. In general, polyurethanes are composed of polyisocyanates and thus complementary compounds with at least two groups reactive toward NCO groups. The groups reactive with the NCO groups are preferably OH, NH2, NHR, or SH groups. The reaction of NCO groups with OH groups leads to the formation of urethane groups. The reaction of NCO groups with amino groups leads to the formation of urea groups. In the context of the present invention, the term “polyurethanes” also includes polyureas and compounds incorporating urethane groups and urea groups. The latter are also referred to below as “polyurethanes containing urea groups.” Compounds containing only one reactive group per molecule lead to a break in the polymer chain and can be used as regulators. Compounds containing two reactive groups per molecule lead to the formation of linear polyurethanes. Compounds with more than two reactive groups per molecule lead to the formation of branched polyurethanes. Polyurethanes within the meaning of the invention can also be linked, for example, by urea, allophanate, biuret, carbodiimide, amide, uretonimine, uretdione, isocyanurate, or oxazolidon structures.

In a particular embodiment, the polymer component of the polymer material (a) contains or consists of at least one polyurethane containing urea groups.

The polymer material (a) preferably contains 15 to 99.5 wt. %, particularly preferably 20 to 99 wt. %, of at least one polyurethane containing urea groups, based on the sum of polyurethane containing urea groups and at least one conductive filler.

In one particular embodiment, the polymer component of the polymer material (a) consists exclusively of at least one polyurethane, in particular of at least one polyurethane containing urea groups.

The following statements on polyurethanes containing urea groups also apply analogously to polyurethanes that do not contain urea groups, i.e., no amine component that has at least two amino groups that are reactive toward NCO groups is used in their production.

Polyurethanes containing urea groups contain at least one polymerized amine component that has at least two amine groups that are reactive toward NCO groups.

The proportion of the amine component is preferably 0.01 to 32 mole %, particularly preferable 0.1 to 10 mole %, based on the components used to produce the polyurethane containing urea groups.

Preferably, the polyurethane (containing urea groups) is low-branched or linear in structure. The polyurethane containing urea groups particularly preferably has a linear structure. This means that the polyurethane containing urea groups is composed of diisocyanates and thus complementary divalent compounds.

Linear polyurethanes (containing urea groups) within the meaning of the invention are polyurethanes containing urea groups and having a degree of branching of 0%.

Low-branched polyurethanes (containing urea groups) preferably have a degree of branching of 0.01 to 20%, in particular of 0.01 to 15%.

The degree of branching of polyurethane (containing urea groups) is preferably 0 to 20%. The degree of branching refers to the proportion of nodes in the polymer chain, i.e., the proportion of atoms that are the starting point of at least three polymer chains branching off from it. Crosslinking is therefore understood to mean that a branching polymer chain opens into a second branching polymer chain.

Groups that are reactive toward NCO groups preferably have at least one active hydrogen atom.

Suitable complementary compounds are low-molecular-weight diols and polyols, polymeric polyols, low-molecular-weight diamines and polyamines with primary and/or secondary amino groups, polymeric polyamines, amine-terminated polyoxyalkylene polyols, compounds with at least one hydroxyl group and at least one primary or secondary amino group in the molecule, in particular amino alcohols.

Suitable low-molecular-weight diols (hereinafter referred to as “diols”) and low-molecular-weight polyols (hereinafter referred to as “polyols”) have a molecular weight of 60 to less than 500 g/mole. Suitable diols include, for example, ethylene glycol, propane-1,2-diol, propane-1,3-diol, butane-1,2-diol, butane-1,3-diol, butane-1,4-diol, butane-2,3-diol, pentane-1,2-diol, pentane-1,3-diol, pentane-1,4-diol, pentane-1,5-diol, pentane-2,3-diol, pentane-2,4-diol, hexane-1,2-diol, hexane-1,3-diol, hexane-1,4-diol, hexane-1,5-diol, hexane-1,6-diol, hexane-2,5-diol, heptane-1,2-diol, 1,7-heptanediol, 1,8-octanediol, 1,2-octanediol, 1,9-nonanediol, 1,2-decanediol, 1,10-decanediol, 1,2-dodecanediol, 1,12-dodecanediol, 1,5-hexadiene-3,4-diol, 1,2- and 1,3-cyclopentanediols, 1,2-, 1,3-, and 1,4-cyclohexanediols, 1,1-, 1,2-, 1,3-, and 1,4-bis(hydroxymethyl)cyclohexanes, 1,1-, 1,2-, 1,3-, and 1,4-bis(hydroxyethyl)cyclohexanes, neopentyl glycol, (2)-methyl-2,4-pentanediol, 2,4-dimethyl-2,4-pentanediol, 2-ethyl-1,3-hexanediol, 2,5-dimethyl-2,5-hexanediol, 2,2,4-trimethyl-1,3-pentanediol, pinacol, diethylene glycol, triethylene glycol, dipropylene glycol, tripropylene glycol.

Suitable polyols include compounds with at least three OH groups, e.g., glycerol, trimethylolmethane, trimethylolethane, trimethylolpropane, 1,2,4-butanetriol, tris(hydroxy-methyl)amine, tris(hydroxyethyl)amine, tris(hydroxypropyl)amine, pentaerythritol, bis(tri-methylolpropane), di(pentaerythritol), di- tri- or oligoglycerols, or sugars, such as glucose, tri- or higher functional polyetherols based on tri- or higher functional alcohols and ethylene oxide, propylene oxide or butylene oxide, or polyesterols. Glycerol, trimethylolethane, trimethylolpropane, 1,2,4-butanetriol, pentaerythritol, and their polyetheroies based on ethylene oxide or propylene oxide are particularly preferred. Since these compounds lead to branching, they are preferably used in an amount not exceeding 5 wt. %, in particular not exceeding 1 wt. %, based on the total weight of the compounds complementary to the isocyanates. Specifically, no polyols are used.

Suitable polymeric diols and polymeric polyols preferably have a molecular weight of 500 to 5000 g/mole. The polymeric diols are preferably selected from polyether diols, polyesterdiols, polyether ester diols, and polycarbonate diols. The ester group-containing polymeric diols and polyols may have carbonate groups instead of or in addition to carboylic acid ester groups.

Preferred polyether diols include polyethylene glycols H0(CH2CH20)n-H, polypropylene glycols H0(CH[CH3]CH2O)n-H, wherein n is an integer and n≥4, polyethylene polypropylene glycols, wherein the sequence of ethylene oxide and propylene oxide units may be block or random, polytetramethylene glycols (polytetrahydrofurans), poly-1,3-propanediols or mixtures of two or more representatives of the foregoing compounds. One or else both hydroxyl groups in the above-mentioned diols may be substituted by SH groups.

Preferred polyester diols are those obtained by reacting bivalent alcohols with bivalent carboxylic acids. Instead of the free polycarboxylic acids, the corresponding polycarboxylic acid anhydrides or corresponding polycarboxylic acid esters of lower alcohols or their mixtures can also be used to produce the polyester diols. The polycarboxylic acids can be aliphatic, cycloaliphatic, araliphatic, aromatic, or heterocyclic and optionally substituted, for example by means of halogen atoms, and/or unsaturated. By way of example, the following are mentioned: cortic acid, azelaic acid, phthalic acid, isophthalic acid, phthalic anhydride, tetrahydrophthalic anhydride, hexahydrophthalic anhydride, tetrachlorophthalic anhydride, endomethylenetetrahydrophthalic anhydride, glutaric anhydride, maleic acid, maleic anhydride, fumaric acid, dimeric fatty acids. Dicarboxylic acids of the general formula HOOC-(CH2)y-COOH, wherein y is a number from 1 to 20, preferably an even number from 2 to 20, e.g., succinic acid, adipic acid, sebacic acid, and dodecanedicarboxylic acid.

The polyvalent alcohols that come into consideration are, for example. ethylene glycol, propane-1,2-diol, propane-1,3-diol, butane-1,3-diol, butene-1,4-diol, butyne-1,4-diol, pentane-1,5-diol, neopentyl glycol, bis-(hydroxymethyl)-cyclohexanes, such as 1,4-bis(hydroxymethyl)cyclohexane, 2-methyl-propane-1,3-diol, methylpentanediols, furthermore diethylene glycol, triethylene glycol, tetraethylene glycol, polyethylene glycol, dipropylene glycol, polypropylene glycol, dibutylene glycol, and polybutylene glycols. Preferred are alcohols of the general formula HO-(CH2)x-OH, wherein x is a number from 1 to 20, preferably an even number from 2 to 20. Examples include ethylene glycol, butane-1,4-diol, hexane-1,6-diol, octane-1,8-diol, and dodecane-1,12-diol. Neopentyl glycol is furthermore preferred. Suitable polyether diols can be obtained in particular by polymerizing ethylene oxide, propylene oxide, butylene oxide, tetrahydrofuran, styrene oxide, or epichlorohydrin with itself, e.g., in the presence of BF3 or by addition of these compounds, optionally in a mixture or successively, to start components with reactive hydrogen atoms, such as alcohols or amines, e.g., water, ethylene glycol, propane-1,2-diol, propane1,3-diol, 2,2-bis(4-hydroxyphenyl)-propane, or aniline. A particularly preferred polyether diol is polytetrahydrofuran. Suitable polytetrahydrofurans can be prepared by cationic polymerization of tetrahydrofuran in the presence of acidic catalysts, such as sulfuric acid or fluorosulfuric acid. Such production methods are familiar to the person skilled in the art.

Preferred are polycarbonate diols as can be obtained, for example, by reacting phosgene with an excess of the low-molecular-weight alcohols mentioned as structural components for the polyester polyols.

Optionally, lactone-based polyester diols can also be used, wherein these are homopolymerizates or copolymerizates of lactones, preferably hydroxyl-terminated addition products of lactones to suitable difunctional starter molecules. Lactones are preferably those derived from compounds of the general formula HO-(CH2)z-COOH, wherein z is a number from 1 to 20 and one H atom of a methylene unit may also be substituted by a C1 to C4 alkyl moiety. Examples include ε-caprolactone, β-propiolactone, γ-butyrolactone, and/or methyl-γ-caprolactone, and mixtures thereof. Suitable starter components are, e.g., the low-molecular-weight bivalent alcohols mentioned above as structural components for the polyester polyols. The corresponding polymerizates of ε-caprolactone are particularly preferred. Lower polyester diols or polyether diols can also be used as starters for the production of lactone polymerizates. Instead of the polymerizates of lactones, the corresponding, chemically equivalent polycondensates of the hydroxycarboxylic acids corresponding to the lactones can also be used.

Polycarbonate ester polyether diols and polycarbonate ester polyether polyols are particularly preferred.

Suitable low-molecular-weight diamines and polyamines with primary and/or secondary amino groups have a molecular weight of 32 to less than 500 g/mole. Diamines containing two amino groups selected from the group of primary and secondary amino groups are preferred. Suitable aliphatic and cycloaliphatic diamines include ethylenediamine, N-alkyl-ethylenediamine, propylenediamine, 2,2-dimethyl-1,3-propylenediamine, N-alkylpropylenediamine, butylenediamine, N-alkylbutylenediamine, pentanediamine, hexamethylenediamine, N-alkylhexamethylenediamine, heptanediamine, octanediamine, nonanediamine, decanediamine, dodecanediamine, hexadecanediamine, toluylenediamine, xylylenediamine, diaminodiphenyl-methane, diaminodicyclohexylmethane, phenylenediamine, cyclohexylenediamine, bis(aminomethyl)cyclohexane, diaminodiphenylsulfone, isophoronediamine, 2-butyl-2-ethyl-1,5-pentamethylenediamine, 2,2,4- or 2,4,4-trimethyl-1,6-hexamethylenediamine, 2-aminopropylcyclohexylamine, 3(4)-aminomethyl-1-methylcyclohexylamine, 1,4-diamino-4-methylpentane.

Low-molecular-weight aromatic diamines and polyamines can also be used to produce the compositions according to exemplary embodiments of the invention. Aromatic diamines are preferably selected from bis-(4-amino-phenyl)-methane, 3-methylbenzidine, 2,2-bis-(4-aminophenyl)-propane, 1,1-bis-(4-aminophenyl)-cyclohexane, 1,2-diaminobenzene, 1,4-diaminobenzene, 1,4-diaminonaphthalene, 1,5-diaminonaphthalene, 1,3-diaminotoluene, m-xylylenediamine, N,N′-dimethyl-4,4′-biphenyl-diamine, bis-(4-methyl-aminophenyl)-methane, 2,2-bis-(4-methylaminophenyl)-propane, or mixtures thereof.

The low-molecular-weight diamines and polyamines used to prepare the compositions according to exemplary embodiments of the invention preferably have a proportion of aromatic diamines and polyamines on all diamines and polyamines of at most 50 mole %, particularly preferably of at most 30 mole %, especially of at most 10 mole %. In a particular embodiment, the low-molecular-weight diamines and polyamines used to produce the compositions according to the invention do not contain any aromatic diamines or polyamines. In a further particular embodiment for producing two-component (2K) polyurethanes according to the invention, aromatic diamines and polyamines are used. The proportion of aromatic diamines and polyamines in all diamines and polyamines is then at most 50 mole %, preferably at most 30 mole %, especially at most 10 mole %.

Suitable polymeric polyamines preferably have a molecular weight of 500 to 5000 g/mole. These include polyethyleneimines and amine-terminated polyoxyalkylene polyols, such as α,ω-diaminopolyethers, which can be produced by aminating polyalkylene oxides with ammonia. Special amine-terminated polyoxyalkylene polyols are so-called jeffamines or amine-terminated polytetramethylene glycols.

Suitable compounds having at least one hydroxyl group and at least one primary or secondary amino group in the molecule include dialkanolamines, such as diethanolamine, dipropanolamine, diisopropanol-amine, 2-amino-1,3-propanediol, 3-amino-1,2-propanediol, 2-amino-1,3-propanediol, dibu-tanolamine, diisobutanolamine, bis(2-hydroxy-1-butyl)amine, bis(2-hydroxy-1-propyl)amine, and dicyclohexanolamine.

Of course, it is also possible to use mixtures of the above-mentioned amines.

According to embodiments of the invention, the polyurethane containing urea groups contains at least one amine component containing amine groups as a copolymerized component, which has at least two amine groups reactive toward NCO groups. This leads to the formation of urea groups during the polyaddition.

In a preferred embodiment, the polyurethane containing urea groups contains at least one diamine component copolymerized with it.

The polymerized diamine component is preferably selected from ethylenediamine, 1,3-propylenediamine, 1,4-tetramethylenediamine, 1,5-pentamethyldiamine, 1,6-hexamethylenediamine, 2-methylpentamethylenediamine, 1,7-heptamethylenediamine, 1,8-octamethylenediamine, 1,9-nonamethylenediamine, 1,10-diaminododecane, 1,12-diaminoododecane, 2,2,4-trimethylhexamethylenediamine, 2,4,4-trimethylhexamethylenediamine, 2,3,3-trimethylhexamethylenediamine, 1,6-diamino-2,2,4-trimethylhexane, 1-amino-3-aminomethyl-3,5,5-trimethylcyclohexane, 1,4-cyclohexylenediamine, bis-(4-aminocyclohexyl)-methane, isophoronediamine, 1-methyl-2,4-diaminocyclohexanes, and mixtures thereof.

Isocyanates are N-substituted organic derivatives (R—N═C═O) of isocyanic acid (HNCO). Organic isocyanates are compounds in which the isocyanate group (-N=C=O) is bonded to an organic moiety. Polyfunctional isocyanates are compounds having two or more (e.g., 3, 4, 5, etc.) isocyanate groups in the molecule.

The polyisocyanate is generally selected from difunctional and polyfunctional isocyanates, the allophanates, isocyanurates, uretdiones, or carbodiimides of difunctional isocyanates, and mixtures thereof. The polyisocyanate preferably contains at least one difunctional isocyanate. In particular, difunctional isocyanates (diisocyanates) are used.

Suitable polyisocyanates are generally all aliphatic and aromatic isocyanates, provided that they have at least two reactive isocyanate groups. In the context of the invention, the term “aliphatic diisocyanates” also comprises cycloaliphatic (alicyclic) diisocyanates.

In a preferred embodiment, the polyurethane (containing urea groups) contains incorporated aliphatic polyisocyanates, wherein the aliphatic polyisocyanate may be replaced by up to 80 wt. %, preferably up to 60 wt. %, based on the total weight of the polyisocyanates, by at least one aromatic polyisocyanate. In one particular embodiment, the polyurethane containing urea groups contains only incorporated aliphatic polyisocyanates.

The polyisocyanate component preferably has an average content of 2 to 4 NCO groups. Diisocyanates, i.e., esters of isocyanic acid having the general structure O═C═N—R′—N═C═O, wherein R′ is an aliphatic or aromatic moiety, are preferred.

Suitable polyisocyanates are selected from compounds with 2 to 5 isocyanate groups, isocyanate prepolymers with an average number of 2 to 5 isocyanate groups, and mixtures thereof. These include aliphatic, cycloaliphatic, and aromatic di-, tri- and higher polyisocyanates.

The polyurethane (containing urea groups) preferably contains at least one aliphatic polyisocyanate incorporated therein. Suitable aliphatic polyisocyanates are selected from ethylene diisocyanate, propylene diisocyanate, tetramethylene diisocyanate, pentamethylene diisocyanate, hexamethylene diisocyanate (HDI), 1,12-diisocyanatododecane, 4-isocyanatomethyl-1,8-octamethylene diisocyanate, triphenylmethane-4,4′,4′,4″-triisocyanate, 1,6-diisocyanato-2,2,4-trimethylhexane, 1,6-diisocyanato-2,4,4,4-trimethylhexane, isophorone diisocyanate (=3-isocyanato-methyl-3,5,5-trimethylcyclohexylisocyanate, 1-isocyanato-3-isocyanatomethyl-3,5,5-trimethylcyclohexane, IPDI), 2,3,3-trimethylhexamethylene diisocyanate, 1,4-cyclohexylene diisocyanate, 1-methyl-2,4-diisocyanatocyclohexane, dicyclohexylmethane-4,4′-diisocyanate (=methylene-bis(4-cyclohexylisocyanate)).

The aromatic polyisocyanate is preferably selected from 1,3-phenylene diisocyanate, 1,4-phenylene diisocyanate, 2,4- and 2,6-toluylene diisocyanate, and mixtures of isomers thereof, 1,5-naphthylene diisocyanate, 2,4′- and 4,4′-diphenylmethane diisocyanate, hydrogenated 4,4′-diphenylmethane diisocyanate (H12MDI), xylylene diisocyanate (XDI), tetramethylxylene diisocyanate (TMXDI), 4,4′-dibenzyl diisocyanate, 4,4′-diphenyl dimethyl methane diisocyanate, di- and tetraalkyldiphenyl methane diisocyanates, ortho-tolydine diisocyanate (TODI), and mixtures thereof.

In a suitable embodiment, the polyurethane (containing urea groups) contains at least one polyisocyanate with uretdione, isocyanurate, urethane, allophanate, biuret, iminooxadiazine dione, and/or oxadiazine trione structure incorporated therein.

In a preferred embodiment, the polyurethane (containing urea groups) contains at least one aliphatic polyisocyanate with uretdione, isocyanurate, urethane, allophanate, biuret, iminooxadiazine dione, and/or oxadiazine trione structure incorporated therein.

In a further preferred embodiment, the polyurethane (containing urea groups) contains at least one aliphatic polyisocyanate and additionally at least one polyisocyanate based on these aliphatic polyisocyanates with uretdione, isocyanurate, urethane, allophanate, biuret, iminooxadiazine dione and/or oxadiazine trione structure incorporated therein.

These are preferably polyisocyanates or polyisocyanate mixtures with exclusively aliphatically and/or cycloaliphatically bound isocyanate groups and an average NCO functionality of 2 to 4, preferably 2 to 2.6, and particularly preferably 2 to 2.4.

The polyurethane (containing urea groups) particularly preferably contains at least one aliphatic diisocyanate, which is selected from hexamethylene diisocyanate, isophorone diisocyanate, and mixtures thereof.

In a preferred embodiment, the polyurethane (containing urea groups) is composed of aliphatic polyisocyanates and thus complementary aliphatic compounds having at least two groups that are reactive toward NCO groups, wherein the aliphatic polyisocyanate may be replaced by up to 50 wt. %, based on the total weight of the polyisocyanates, by at least one aromatic polyisocyanate.

In a particularly preferred embodiment, the polyurethane (containing urea groups) is composed of aliphatic polyisocyanates and thus complementary aliphatic compounds having at least two groups that are reactive toward NCO groups, wherein the aliphatic polyisocyanate may be replaced by up to 30 wt. %, based on the total weight of the polyisocyanates, by at least one aromatic polyisocyanate.

In one particular embodiment, the polyurethane (containing urea groups) is composed of aliphatic polyisocyanates and thus complementary aliphatic compounds having at least two groups that are reactive toward NCO groups.

In one particular embodiment, a diamine-modified polycarbonate ester polyether polyurethane is used as a polyurethane containing urea groups.

In a further preferred embodiment, the polymer component of the polymer material (a) contains or consists of a thermoplastic elastomer (TPE). Suitable and preferred TPEs are those mentioned above, to which reference is made here.

Suitable TPE are selected from thermoplastic polyamide elastomers (TPA), thermoplastic copolyester elastomers (TPC), thermoplastic olefin-based elastomers (TPO), thermoplastic styrene block copolymers (TPS), thermoplastic urethane-based elastomers (TPU), and thermoplastic vulcanizates or crosslinked thermoplastic olefin-based elastomers (TPV).

TPA is commercially available, for example, as PEBAX from Arkema.

TPC is commercially available, for example, as Keyflex from LG Chem.

TPO is commercially available, for example, as Elastron TPO, SaxomerTPE-O from PCW.

TPS is commercially available, for example, as Elastron G and Elastron D, Kraton from Kraton Polymers, as Septon from Kuraray, as Styroflex from BASF, as Thermolast from Kraiburg TPE, as ALLRUNA from ALLOD Werkstoff GmbH & Co. KG, or as Saxomer TPE-S from PCW. TPU is commercially available, for example, as Elastollan from BASF or as Desmopan, Texin, Utechllan from Covestro. TPV is commercially available, for example, as Elastron V, Sariink from DSM.

The thermoplastic elastomer is preferably selected from diene-type rubber, such as polybutadiene, poly(styrene-butadiene), and poly(acrylonitrile-butadiene), saturated rubber obtained by hydrogenating these diene-type rubbers, isoprene rubber, chloroprene rubber, acrylic-type rubber, such as a butyl polyacrylate, an ethylene/propylene, ethylene/propylene-diene, and an ethylene/octene copolymer rubber.

### Polymer Material (b)

In one embodiment, the polymer component of the polymer material b) comprises or consists of at least one polymer selected from so-called high-performance plastics, which are characterized by their temperature resistance but also chemical resistance and good mechanical properties. Such polymers are particularly suitable for applications in the automotive sector.

The polymer component of the polymer material b) is preferably selected from polyesters, polyketones (PK), polyether ketones (PEK), polyetheretherketones (PEEK), polyamides (PA), polyamide-imides (PAI), polyphenylene sulfides (PPS), polyarylsulfones, ABS copolymers, and mixtures (blends) thereof.

A particular embodiment of the polyesters is polyethyleneterephtalates (PET), polybutylene terephthalate (PBT), and polycarbonates (PC).

A particular embodiment of polyamides is high-temperature polyamides (HTPA). These are semi-crystalline or amorphous, thermoplastic, partially aromatic polyamides. They preferably contain at least one polymerized aromatic dicarboxylic acid, in particular selected from terephthalic acid, isophthalic acid, and mixtures of terephthalic acid and isophthalic acid. Preferred HTPAs are selected from PA6.T, PA10.T, PA12.T, PA6.I, PA 10.I, PA 12.1, PA 6.T/6.I, PA6.T/6, PA6.T/10T, PA 10.T/6.T, PA6.T/12.T, PA12.T/6.T, and mixtures thereof.

A further particular embodiment of polyamides is polyphthalamide (PPA).

In a preferred embodiment, the polyketones are selected from polyether ketones, polyetheretherketones, polyaryletherketones, and mixtures thereof.

In another preferred embodiment, the polyarylsulfones are selected from polysulfones (PSU), polyethersulfones (PES), polyphenylenesulfones (PPSU), and blends of PSU and ABS.

In a further preferred embodiment, the polymer component of the polymer material (b) comprises or consists of a polyamide ABS blend.

### Polymer Material (c)

In one embodiment, the polymer component of the polymer material (c) is selected from elastomers, thermoplastic elastomers, and mixtures thereof.

Conductive Filler

The polymer material (a) contains at least one filler for shielding against electromagnetic radiation.

The composition according to various embodiments of the invention as defined above and below comprises, as component a), at least one conductive filler.

The electrically conductive filler can advantageously be in the form of particulate materials or fibers. These include powders, nanoparticulate materials, nanotubes, fibers, etc. The fillers can be coated or uncoated or applied to a carrier material. The geometry of the particulate materials or fibers is not significant. The cross section may be any shape, for example round, oval, triangular, or rectangular. The aspect ratio is in particular in the range of 1 to 10000. The aspect ratio is the quotient of the length and thickness of the particulate material or fiber.

Preferably, at least the conductive filler is selected from carbon nanotubes, carbon fibers, graphite, graphene, conductive carbon black, metal-containing material, such as metal-coated carriers, elemental metals, metal oxides, metal alloys, metal fibers, and mixtures thereof.

Preferred metal-coated carriers include metal-coated carbon fibers, especially nickel-plated carbon fibers and silver-plated carbon fibers. Preferred metal-coated carriers are furthermore silver-coated glass beads. For example, embodiments according to the present invention, can use a polystyrene/polyaniline blend filled with nickel-coated carbon fibers.

Preferably, the conductive filler is not a homogeneous layer consisting of metal. Preferably, the conductive filler is not layers of metals or metal foils obtained by metal vapor deposition.

Suitable elemental metals are selected from cobalt, aluminum, nickel, silver, copper, strontium, iron, and mixtures thereof.

Suitable alloys are selected from strontium ferrite, silver-copper alloy, silver-aluminum alloy, iron-nickel alloy, μ-metals, amorphous metals (metallic glasses), and mixtures thereof.

Suitable metal fibers are man-made fibers consisting of metal, metal alloys, plastic-coated metal, metal-coated plastic, or a core completely encased with metal. Suitable metals and alloys are those mentioned above. Metal fibers preferably comprise or consist of at least one metal selected from iron, copper, aluminum, and alloys thereof. In one particular embodiment, the metal fibers comprise or consist of steel, especially stainless steel.

In one particular embodiment, the conductive filler comprises at least one ferromagnetic material, preferably selected from iron, cobalt, nickel, oxides and mixed oxides thereof, alloys, and mixtures thereof. These fillers are especially suitable for deflecting electromagnetic waves having a low frequency.

In another particular embodiment, the conductive filler comprises at least one carbon-rich conductive material, preferably selected from carbon nanotubes, carbon fibers, graphite, graphene, conductive carbon black, and mixtures thereof. These fillers are especially suitable for reflecting and absorbing electromagnetic waves having a high frequency.

In another embodiment, at least one conductive filler is selected from conductive carbon black, metal-containing material, and mixtures thereof. Specifically, the conductive filler comprises at least one conductive carbon black and at least one metal-containing material. The quantity ratio of carbon black to the metal-containing material is in the range of 5 wt. %:95 wt. % to 95 wt. %:5 wt. %.

The first polymer material a) may contain carbon black as the sole conductive filler. In this case, the input quantity of carbon black is higher than in compositions containing carbon black for coloring and/or as a UV protection agent. When the first polymer material a) contains carbon black as the sole conductive filler, the content of carbon black, based on the total weight of the polymer material a), is 5 to 95 wt. %, particularly preferably 10 to 90 wt. %, in particular 20 to 85 wt. %, based on the total weight of the polymer material a).

In a preferred embodiment, the first polymer material a) contains a mixture of carbon black and at least one component different from carbon black as a conductive filler. Specifically, the component different from carbon black is selected from metal-coated carriers, elemental metals, metal oxides, metal alloys, metal fibers, and mixtures thereof. Specifically, the first polymer material a) contains as conductive filler a mixture of at least one conductive carbon black and at least one metal-containing material.

The filler is generally contained in the polymer matrix in a sufficient proportion to achieve the desired electrical conductivity for the intended application. Customary input quantities of the conductive filler are, for example, in a range of 0.1 to 95 wt. %, based on the total weight of components a) and b). Preferably, the proportion of filler a) is 0.5 to 95 wt. %, particularly preferable 1 to 90 wt. %, based on the total weight of components a) and b).

In a preferred embodiment, the polymer material a) additionally contains at least one conductive polymer which is different from the polyurethane containing urea groups.

Suitable conductive polymers generally have a conductivity of at least 1×103 S m-1 at 25° C., preferably at least 2×103 S m-1 at 25° C.

Suitable conductive polymers are selected from polyanilines, polypyrroles, polythiophenes, polyethylene dioxythiophenes (PEDOT), poly(p-phenylene-vinylenes), polyacetylenes, polydiacetylenes, polyphenylene sulfides (PPS), polyperinaphthalenes (PPN), polyphthalocyanines (PPhc), sulfonated polystyrene polymers, carbon fiber-filled polymers, and mixtures, derivatives, and copolymers thereof.

The proportion by weight of the at least conductive polymer is preferably 0 to 10 wt. %, such as 0.1 to 5 wt. %, based on the total weight of component b).

In one possible embodiment, the polymer material a) additionally contains at least one non-conductive polymer that is different from the polyurethane containing urea groups.

Suitable non-conductive polymers that are different from the polyurethane containing urea groups are preferably selected from polyurethanes, silicones, fluorosilicones, polycarbonates, ethylene-vinyl acetates (EVA), acrylonitrile-butadiene-styrenes (ABS), polysulfones, poly(meth)acrylates, polyvinyl chlorides (PVC), polyphenyl ethers, polystyrenes, polyamides, polyolefins, e.g., polyethylene or polypropylene, polyether ketones, polyetheretherketones, polyimides, polyetherimides, polyethylene terephthalates, polybutylene terephthalates, fluoropolymers, polyesters, polyacetals, e.g., polyoxymethylene (POM), liquid crystal polymers, polyphenylene oxides, polysulfones, polyether sulfones, polystyrenes, epoxides, phenols, chlorosulfonates, polybutadienes, acrylonitrile-butadiene rubbers (ABN), butylene, neoprenes, nitriles, polyisoprenes, natural rubbers, and copolymer rubbers, such as styrene-isoprene-styrenes (SIS), styrene-butadiene-styrenes (SBS), ethylene-propylenes (EPR), ethylene-propylene-diene monomers (EPDM), nitrile-butadienes (NBR), styrene-butadienes (SBR), and copolymers thereof, and mixtures thereof.

Preferably, the proportion by weight of the at least one non-conductive polymer different from the polyurethane containing urea groups is 0 to 20 wt. %, preferably 0 to 15 wt. %, based on the total weight of component a). If such a non-conductive matrix polymer is present, it is present in an amount of at least 0.1, preferably at least 0.5 wt. %, based on the total weight of component a).

The conductive polymer and the non-conductive polymer can be mixed into a mixture of components using standard techniques, such as melt-blending or dispersing the filler particles during polymerization of the matrix polymer (sol-gel method). Homogeneous and heterogeneous blends are possible. No macrophases are present in a homogeneous blend, whereas macrophases are present in a heterogeneous blend.

In a preferred embodiment, the first polymer material (a) contains
a1) 0.5 to 95 wt. % of at least one conductive filler,
a2) 15 to 99.5 wt. % of at least one polymer component,
a3) 0 to 20 wt. % of at least one non-conductive polymer different from a2),
a4) 0 to 10 wt. % of at least one conductive polymer,
a5) optionally at least one additive, wherein each additive is present in an amount of up to 3 wt. %,
optionally at least one solvent.

Suitable additives a5) are selected from antioxidants, heat stabilizers, flame retardants, light protection agents (UV stabilizers, UV absorbers, or UV blockers), catalysts for the crosslinking reaction, thickeners, thixotropic agents, surface active agents, viscosity modifiers, lubricants, dyes, nucleating agents, antistatics, mold release agents, defoamers, bactericides, etc.

In addition, the composition may contain, as component a6) at least one filler and reinforcing material different from components a) to c). The fillers and reinforcing substances mentioned below are also suitable for providing composites for back injection molding, as described above.

The term “filler and reinforcing material” (=component a6)) is broadly understood within the scope of the invention and comprises particulate fillers, fibrous materials, and any desired transition forms. Particulate fillers can have a wide range of particle sizes, from powdery to coarse-grained particles. Organic or inorganic fillers and reinforcing materials can be used as filling material. For example, inorganic fillers, such as carbon fibers, kaolin, chalk, wollastonite, talc, calcium carbonate, silicates, titanium dioxide, zinc oxide, glass particles, e.g., glass beads, nanoscale phyllosilicates, nanoscale aluminum oxide (Al2O3), nanoscale titanium dioxide (TiO2), phyllosilicates, and nanoscale silicon dioxide (SiO2) can be used. The fillers may also be surface-treated.

Suitable phyllosilicates include kaolins, serpentines, talc, mica, vermiculite, illite, smectite, montmorillonite, hectorite, double hydroxides, and mixtures thereof. The phyllosilicates can be surface-treated or untreated.

Furthermore, one or more fibrous materials can be used. These are preferably selected from known inorganic reinforcement fibers, such as boron fibers, glass fibers, silica fibers, ceramic fibers, and basalt fibers; organic reinforcement fibers, such as aramid fibers, polyester fibers, nylon fibers, and polyethylene fibers; and natural fibers, such as wood fibers, flax fibers, hemp fibers, and sisal fibers.

The component a6) is preferably used, if present, in an amount of 1 to 80 wt. %, based on the total amount of components a1) to a6).

As a further embodiment, the composition according to the invention can be in the form of foam. Foam within the meaning of the invention is a porous, at least partially open-cell structure with intercommunicating cells.

In order to produce a polyurethane foam, the components of the composition according to exemplary embodiments of the invention can be mixed, foamed, and cured, optionally after prepolymerization of at least part thereof. Curing is preferably carried out by chemical crosslinking. In principle, foaming can be carried out by the carbon dioxide formed when the isocyanate groups react with water; however, the use of other propellants is likewise possible. In principle, propellants from the hydrocarbon class, such as C3-C6-alkanes, e.g., n-butane, sec-butane, isobutane, n-pentane, isopentane, cyclopentane, hexanes, etc. or halogenated hydrocarbons, such as dichloromethane, dichloromonofluoromethane, chlorodifluoroethanes, 1,1-dichloro-2,2,2-trifluoroethane, 2,2-dichloro-2-fluoroethane, in particular chlorine-free fluorocarbons, such as difluoromethane, trifluoromethane, difluoroethane, 1,1,1,2-tetrafluoroethane, 1,1,2,2-tetrafluoroethane, 1,1,1,3,3-pentafluoropropane, 1,1,1,3,3,3-hexafluoropropane, 1,1,1,3,3-pentafluorobutane, heptafluoropropane, or sulfur hexafluoride can be used. Mixtures of these propellants are also possible. Subsequent curing is typically carried out at a temperature of about 10 to 80° C., especially 15 to 60° C., especially at room temperature. After curing, any residual moisture that is still present can, if necessary, be removed by conventional methods, such as convective air drying or microwave drying.

The polymer component of the polymer material (a) is preferably in the form of a two-component (2K) polymer composition. Suitable (2K) polymer compositions comprise or consist of elastomers, thermoplastic elastomers, and mixtures thereof. Preferred are 2K silicone rubbers, 2K polyolefins, 2K polyurethanes, and mixtures thereof.

In a further preferred embodiment, the polymer component of the polymer material (a) is in the form of a two-component (2K) polyurethane composition. Suitable two-component polyurethane coatings contain, for example, a component (I) and a component (II), wherein component (I) contains at least one of the aforementioned compounds having at least two groups that are reactive toward NCO groups, as used for producing the polyurethanes containing urea groups. Alternatively or additionally, component (I) may contain a prepolymer containing at least two groups that are reactive toward NCO groups. Component (II) contains at least one of the aforementioned polyisocyanates as used in the production of polyurethanes containing urea groups. Alternatively or additionally, component (II) may contain a prepolymer containing at least two NCO groups. Optionally, components (I) and/or (II) may contain further oligomers and/or polymeric constituents. For example, in the case of an aqueous two-component (2K) polyurethane composition, component (I) may comprise one or more further polyurethane resins and/or acrylate polymerizates and/or acrylated polyesters and/or acrylated polyurethanes. The further polymers are generally water-soluble or water-dispersible and have hydroxyl groups and possibly acid groups or salts thereof. The other previously mentioned components of the polymer material (a) may each be present only in component (I) or (II) or proportionately in both.

The two components (I) and (II) of the two-component (2K) polyurethane composition of the polymer material (a) are prepared by the usual methods from the individual constituents with stirring. The coating compositions from these two components (I) and (II) are likewise produced by stirring or dispersing using the devices customarily used, for example by means of dissolvers or the like, or by means of 2-component dosing and mixing equipment which are likewise customarily used.

The polymer material (a) containing a two-component (2K) polyurethane composition may be in the form of an aqueous coating. In the ready-to-use state, a suitable aqueous two-component (2K) polyurethane coating generally comprises, based on the total weight of the composition:

0.5 to 95 wt. % of at least one conductive filler (previously defined as component a)),

15 to 99.5 wt. % of at least one polyurethane, especially one polyurethane containing urea groups (previously defined as component a2))
0 to 20 wt. % of at least one non-conductive polymer different from a2) (previously defined as component a3)),

0 to 7 wt. % of at least one conductive polymer (previously defined as component a4)),

0 to 90 wt. %, preferably 10 to 80 wt. %, of at least one solvent,

further additives, fillers and reinforcing materials adding up to 100 wt. %.

With a two-component (2K) polyurethane composition according to exemplary embodiments of the invention, plastics, such as ABS, AMMA, ASA, CA, CAB, EP, UF, CF, MF, MPF, PF, PAN, PA, PC, PE, HDPE, LDPE, LLDPE, UHMWPE, PET, PMMA, PP, PS, SB, PUR, PVC, RF, SAN, PBT, PPE, POM, PUR-RIM, SMC, BMC, PP-EPDM, and UP (short designations according to DIN 7728T1) can be coated. The plastics to be coated can of course also be polymer blends, modified plastics, or fiber-reinforced plastics. Furthermore, the two-component (2K) polyurethane composition according to various embodiments of the invention can also be applied to other substrates, such as metal, wood, or paper, or mineral substrates.

In the case of non-functionalized and/or non-polar substrate surfaces, these can be subjected to a pretreatment, such as with plasma or flame, before coating.

If desired, the substrates may be primed prior to coating with the two-component (2K) polyurethane composition according to exemplary embodiments of the invention. All common primers can be used, both conventional and aqueous primers. Of course, both radiation-curable and thermally curable or dual cure primers can be used.

Application can be carried out using common methods, such as spraying, knife-coating, dipping, brushing, or by means of coil coating.

The coating compositions according to various embodiments of the invention are usually cured at temperatures not exceeding 250° C., preferably at temperatures not exceeding 150° C., and most preferably not exceeding 100° C.

Another subject matter of the invention is a method for producing a composition for shielding against electromagnetic radiation, comprising the steps of:
a) providing at least one conductive filler, and
b) mixing the at least one conductive filler with the polymers forming the polymer matrix.

A further subject matter of the invention is a method for producing a substrate shielded from electromagnetic radiation and comprising or consisting of a composition for shielding electromagnetic radiation, as previously defined, in which such a composition for shielding against electromagnetic radiation is provided, and

the substrate is formed (shaping) from the composition for shielding against electromagnetic radiation; or

the composition for shielding against electromagnetic radiation is incorporated (incorporation) into a substrate; or

a substrate is at least partially coated (coating) with the composition for shielding against electromagnetic radiation.

Within the scope of the invention, “substrate” is understood to mean any sheet-like structure onto which the composition according to exemplary embodiments of the invention can be applied or into which the composition according to the invention can be incorporated or which consists of the composition according to exemplary embodiments of the invention. Sheet-like structures include, for example, housings, cable sheaths, shells, covers, sensor systems.

A preferred embodiment comprises a method as defined above, in which a drying and/or curing step additionally follows.

In order to be used in the method according to embodiments of the invention, at least one additive different from the conductive filler a) can be added to the composition for shielding against electromagnetic radiation. Suitable additives are those mentioned above.

### Shaping (=Variant 1)

In a first variant of the method according to embodiments of the invention, the substrate is shaped from the composition for shielding against electromagnetic radiation. The composition according to exemplary embodiments of the invention is plasticized and undergoes a shaping step. These are shaping steps that are familiar to the person skilled in the art, such as cast molding, blow molding, calendering, injection molding, pressing, injection stamping, embossing, extruding, etc.

### Incorporating (=Variant 2)

In a second variant of the method according to embodiments of the invention, the composition for shielding against electromagnetic radiation is incorporated into a substrate.

In principle, suitable incorporation methods are known to the person skilled in the art and comprise those normally used for compounding plastic molding compounds.

Incorporating can be carried out either in the melt or in the solid phase. A combination of these methods is also possible, for example by premixing in the solid phase and subsequent mixing in the melt. Conventional devices, such as kneaders or extruders, can be used.

The composition obtained by incorporating the composition shielding against electromagnetic radiation into the substrate may subsequently be subjected to at least one further method step. This is preferably selected from shaping, drying, curing, or a combination thereof.

### Coating (=Variant 3)

In a third variant of the method according to embodiments of the invention, a substrate is at least partially coated with the composition for shielding against electromagnetic radiation.

The substrates are coated with the compositions described above for shielding against electromagnetic radiation using conventional methods that are known to the person skilled in the art. To this end, the composition for shielding against electromagnetic radiation or a coating compound containing it is applied to the substrate to be coated in the desired thickness and optionally dried and/or optionally partially or completely cured. This process can be repeated one or more times if desired. The application to the substrate can be carried out in known ways, e.g., by dipping, injecting, puttying, knife-coating, brushing, rolling, dip-coating, rolling, casting, laminating, back injection molding, in-mold coating, co-extruding, screen printing, pad printing, spinning, reactive injection molding (RIM), compression molding, and transfer molding. In a preferred embodiment, the composition for shielding against electromagnetic radiation comprises at least one thermoplastic elastomer (TPE) and is applied to the substrate to be coated by laminating, back injection molding, co-extruding, reactive injection molding (RIM), compression molding, or transfer molding.

The coating can be applied one or more times, for example, by a spraying method, such as air pressure, airless, or electrostatic spraying methods.

The coating thickness, i.e., the thickness of the conductive layer, is generally in the range of about 100 to 5000 μm, preferably 500 to 2000 μm.

The application and optionally drying and/or curing of the coatings can be applied under normal temperature conditions, i.e., without heating the coating, but also at elevated temperature. The coating can be dried and/or cured, for example, during and/or after application at elevated temperature, for example at 25 to 200° C., preferably 30 to 100° C.

A further subject matter of the invention is the use of the composition according to exemplary embodiments of the invention, as defined above, for shielding electromagnetic radiation. In particular, the composition according to embodiments of the invention, as previously defined, can be used for shielding electromagnetic radiation in electronic housings.

The substrates according to exemplary embodiments of the invention produced by the method according to embodiments of the invention and shielded from electromagnetic radiation are advantageously suitable for use in electric vehicles, aircraft, and spacecraft. A preferred field of application is the use of the substrates according to exemplary embodiments of the invention and the substrates produced by the method according to exemplary embodiments of the invention in electric vehicles and drones. In general, an electric vehicle is a means of transportation that is at least temporarily or partially powered by electric energy. In this case, the energy can be generated in the vehicle, stored in batteries, or supplied temporarily or permanently from outside (e.g., by busbars, overhead lines, induction, etc.), wherein combinations of different forms of energy supply are possible. Battery-operated vehicles are internationally also referred to as Battery Electric Vehicle (BEV). Examples of electric vehicles are road vehicles, railroad vehicles, watercraft, or aircraft, such as electric vehicles, electric motor scooters, electric motorcycles, electric three wheelers, battery and trolley buses, electric trucks, electric railroads (railroads and tramways), electric bicycles, and electric scooters. Electric vehicles within the meaning of the invention are also hybrid electric vehicles (HEV) and fuel cell vehicles (Fuel Cell (Electric) Vehicle, FC(E)V). In fuel cell vehicles, electric energy is generated from hydrogen or methanol by a fuel cell and converted directly into movement by the electric drive or temporarily stored in a battery.

In electromobility, a distinction is made between four core areas in which the shielding of electromagnetic radiation is of critical importance: the power electronics, the battery, the e-motor, and the navigation and communication equipment. The substrates according to exemplary embodiments of the invention are advantageously suitable for the production of electronic housings for e-mobility vehicles in these four areas.

Modern electric vehicles are based on brushless electric motors, such as asynchronous machines or permanently excited synchronous machines (brushless DC machine). The commutation of the supply voltage in the phases of the motor, and thus the generation of the rotating field required for operation, is carried out electronically by so-called inverters. When braking, the electric motor acts as a generator and supplies an AC voltage that can be rectified by the inverter and fed to the traction battery (recuperation). Both fuel cells and the batteries in electric cars supply higher voltages than the 12 V DC or 24 V DC previously known in the automotive sector. A low-voltage electrical system is still required for many on-board electronics components. To this end, DC/DC converters are used to convert the battery's high voltage into a correspondingly lower voltage and supply it to consumers, such as air conditioning, power steering, lighting, etc. Another important power electronics component in the electric car is the on-board charger. Electric charging stations for supplying electric vehicles provide either single-phase or three-phase alternating current or direct current. Charging the traction batteries necessarily requires direct current, which is generated by rectifying and converting the alternating current with the aid of an on-board charger. The substrates according to exemplary embodiments of the invention are particularly suitable for shielding electromagnetic radiation from inverters, DC/DC converters, and on-board chargers. The substrates according to exemplary embodiments of the invention are also particularly suitable for shielding navigation and communication equipment, such as GPS systems in particular, from electromagnetic radiation.

Advantageously, the compositions according to the exemplary embodiments of the invention, as previously defined, are also suitable for improving NVH (noise, vibration, harshness) properties in addition to shielding against electromagnetic radiation.

Furthermore, the compositions according to the exemplary embodiments of the invention, as previously defined, are suitable for producing seals or containers having a good sealing effect.

The EMI-shielding compositions are preferably based on the following compositions:

Polymer Matrix:

The EMI shielding composition contains one or more than one of the following polymer matrices:

compounded TPE (comprising anti-aging agents, plasticizers, and optionally other additives) or

compounded TPU (comprising anti-aging agents, plasticizers, and optionally other additives) or

compounded TPV (comprising anti-aging agents, plasticizers, and optionally other additives)

proportion: 20-95 wt. % each, preferably 40-95 wt. %, based on the total weight of the EMI-shielding composition?

Fillers:

The EMI-shielding composition contains one or more than one of the following conductive fillers:

Conductive Carbon Black:

is used for coloring, improving electrical conductivity, UV protection

proportion: 5-30 wt. %, based on the total weight of the EMI-shielding composition

Carbon Fibers:

are used for improving electrical conductivity

proportion: 5-30 wt. %, based on the total weight of the EMI-shielding composition

Graphites:

are used for improving electrical conductivity

particle sizes: 5 μm to 600 μm

proportion: 5-30 wt. %, based on the total weight of the EMI-shielding composition

Graphene/Carbon Nanotubes:

are used for improving electrical conductivity

particle sizes: 0.01 μm to 100 μm

proportion: 5-30 wt. %, based on the total weight of the EMI-shielding composition

Metal Fibers:

are used for improving electrical conductivity

metals used (including alloys): iron, stainless steel, copper, aluminum

cross-sectional geometries: round, triangular, square, rectangular

diameter: 1 μm to 500 μm

length: 0.5 mm to 15 mm

aspect ratio: 1 to 15000

proportion: 5-50 wt. %, based on the total weight of the EMI-shielding composition

Formulation:

| Type | Percent by weight |
|---|---|
| TPE (SEBS) | 65 |
| Conductive carbon black | 5 |
| Graphite | 10 |
| Carbon fiber | 5 |
| Stainless steel fiber | 15 |

The composition according to various embodiments of the invention is produced in an extruder and subsequently granulated. Shaping into standardized ASTM specimens is carried out by injection molding. Alternatively, plates having dimensions 1 mm×150 mm×150 mm are produced by compression molding, and the ASTM specimens are milled therefrom.

This formulation is used to obtain good EMI-shielding specimens.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method of producing a substrate shielded from electromagnetic radiation, the method comprising:
i) providing a first polymer material (a) or a precursor of the first polymer material (a) containing at least one conductive filler and at least a second polymer material (b) or a precursor of the second polymer material (b);
subjecting the first polymer material (a) or the precursor of the first polymer material (a) and the second polymer material (b) or the precursor of the second polymer material (b) to shaping with material bonding of the first and second polymer materials (a) and (b), and polymerizing, if present, the precursors so as to obtain the substrate; and
iii) at least partially surrounding an electronic component with the substrate obtained in step ii),
wherein a polymer component of the first polymer material (a) comprises a at least one thermoplastic elastomer, selected from the group consisting of thermoplastic polyamide elastomers, thermoplastic copolyester elastomers, thermoplastic olefin-based elastomers, thermoplastic styrene block copolymers, thermoplastic polyurethane-based elastomers, thermoplastic vulcanizates, crosslinked thermoplastic olefin-based elastomers, polyether block amides, and mixtures thereof.

2. (canceled)

3. The method according to claim 1, the method further comprising using at least one of the first polymer material (a), the precursor for the first polymer material (a), the second polymer material (b), and/or the precursor for the second polymer material (b) in flowable form for shaping in step ii) or in a shapable form under the conditions of step ii).

4. The method according to claim 1, the method further comprising forming at least one material bond and optionally additionally at least one form fit in step ii).

5. The method according to claim 1, the method further comprising:
materially bonding and/or form fitting the polymer materials (a) and (b) to at least one third polymer material (c) or a precursor of the third polymer material (c).

6. The method according to claim 1, the method further comprising:
providing a third polymer material (c); and
materially bonding and/or form fitting a combination of the first polymer material (a), the second polymer material (b), and optionally the third polymer material (c) to at least one further third polymer material (c) or a precursor of the further third polymer material (c), and optionally subjecting the combination to further shaping,
wherein step the material bonding and/or form fitting can be repeated one or more times.

7. The method according to claim 1, the method further comprising providing one of the first polymer material (a) or the second polymer material (b) in the form of a composite, preferably a layered composite.

8. (canceled)

9. The method according to claim 7, wherein in step i), the composite comprises the polymer component of the first polymer material (a) or a polymer component of the second polymer material (b) as a coating on a polymer film.

10. (canceled)

11. (canceled)

12. (canceled)

13. The method according to claim 1, the method further comprising:
materially bonding, by multi-component injection molding, the first polymer material (a) and the second polymer material (b) in step i),
wherein the first polymer material (a) and the second polymer material (b) provided in step i) are both plasticizable.

14. (canceled)

15. (canceled)

16. The method according to claim 1, the method further comprising:
providing a polymer component of the second polymer material (b) and a polymer component of a third polymer material (c); and
independently selecting the polymer component of the second polymer material (b) and the polymer component of the third polymer material (c) from polyurethanes, silicones, fluorosilicones, polycarbonates, ethylene vinyl acetates, acrylonitrile-butadiene-acrylates, acrylonitrile-butadiene rubbers, acrylonitrile-butadiene-styrenes, acrylonitrile-methyl methacrylates, acrylonitrile-styrene-acrylates, cellulose acetates, cellulose acetate butyrates, polysulfones, poly(meth)acrylates, polyvinyl chlorides, polyphenylene ethers, polystyrenes, polyamides, polyolefins, polyketones, polyetherketones, polyimides, polyetherimides, polyethylene terephthalates, polybutylene terephthalates, fluoropolymers, polyesters, polyacetals, liquid crystal polymers, polyether sulfones, epoxy resins, phenolic resins, chlorosulfonates, polybutadienes, polybutylene, polyneoprenes, polynitriles, polyisoprenes, natural rubbers, styrene-isoprene-styrenes, styrene-butadiene-styrenes, ethylene-propylenes, ethylene-propylene-diene rubbers, styrene-butadiene rubbers, their copolymers, and mixtures thereof.

17. (canceled)

18 (canceled)

19. (canceled)

20. The method according to claim 1, the method further comprising selecting the polymer component of the first polymer material (a) from SEBS, SEPS, SBS, SEEPS, SiBS, SIS, SIBS, or mixtures thereof, in particular SBS, SEBS, SEPS, SEEPS, MBS.

21. The method according to claim 1, the method further comprising selecting the polymer component of the first polymer material (a) from a thermoplastic olefin-based elastomer, in particular from PP/EPDM and ethylene-propylene copolymers.

22. The method according to claim 1, the method further comprising selecting the polymer component of the first polymer material (a) from a thermoplastic polyurethane-based elastomer, in particular derived from at least one polymeric polyol, specifically selected from at least one polyester diol, polyether diol, polycarbonate diol, and mixtures thereof.

23. The method according to claim 1, the method further comprising:
providing a polymer component of a third polymer material (c), and
selecting the polymer component of the polymer material (c) from elastomers, thermoplastic elastomers, and mixtures thereof.

24. (canceled)

25. The method according to claim 1, wherein the polymer component of the first polymer material (a) further comprises at least one polyurethane containing urea groups.

26. (canceled)

27. The method according to claim 1, wherein the polymer component of the first polymer material (a) further comprises at least one conductive polymer.

28. (canceled)

29. The method according to claim 1, the method further comprising selecting the at least one conductive filler from carbon nanotubes, carbon fibers, graphite, graphene, conductive carbon black, metal-coated carriers, elemental metals, metal oxides, metal alloys, metal fibers, and mixtures thereof.

30. (canceled)

31 (canceled)

32. (canceled)

33. The method according to claim 1, wherein the first polymer material (a) comprises:
a1) 0.5 to 95 wt. % of the at least one conductive filler;
a2) 15 to 99.5 wt. % of the at least one polymer component;
a3) 0 to 20 wt. % of at least one non-conductive polymer different from a2);
a4) 0 to 10 wt. % of at least one conductive polymer;
a5) optionally at least one additive, wherein each additive is present in an amount of up to 3 wt. %; and
optionally at least one solvent.

34. The substrate obtainable by the method of claim 1.

35. A device for shielding against electromagnetic radiation, comprising the substrate as defined in claim 34.

36. (canceled)

37. Electric housings, in particular electric vehicles, aircraft, spacecraft, preferably electric vehicles and drones containing the substrate as defined in claim 34.

38. (canceled)

39. The method of claim 1, wherein step iii) comprises coating the electronic component with the substrate obtained in step ii).

40. The method of claim 1, wherein step iii) comprises encasing the electronic component with the substrate obtained in step ii).

41. The method of claim 1, wherein step iii) comprises embedding the electronic component into the substrate obtained in step ii),
